(19) United States
(12) Patent Application Publication
(10) Pub. No.: US 2020/0388735 A1
(43) Pub. Date: Dec. 10, 2020

(54) ELECTRICAL CONTACT STRUCTURE FOR LIGHT EMITTING DIODE

(71) Applicant: MIKRO MESA TECHNOLOGY CO., LTD., Apia (WS)

(72) Inventor: Li-Yi CHEN, Tainan City (TW)

(21) Appl. No.: 16/726,219

(22) Filed: Dec. 23, 2019

Related U.S. Application Data
(63) Continuation-in-part of application No. 16/432,918, filed on Jun. 5, 2019.

(51) Int. Cl. H01L 33/62; H01L 33/36; H01L 33/44

(52) U.S. Cl. CPC H01L 33/62; H01L 33/36; H01L 2933/0066; H01L 2933/0025; H01L 33/44

(57) ABSTRACT

An electrical contact structure including a substrate, first/second conductive pads, a light-emitting diode, a cured positive photoresist layer, and a top electrode is provided. A thickness of a second type semiconductor layer of the light-emitting diode is greater than a thickness of a first type semiconductor layer of the light-emitting diode. The cured positive photoresist layer is in contact with the light-emitting diode, which exposes a top surface of the second conductive pad through a via hole therein, and exposes a top surface of the light-emitting diode. A height of the top surface of the light-emitting diode relative to the top surface of the substrate is greater than a height of a top surface of the cured positive photoresist layer relative to the top surface of the substrate. The top electrode covers the top surface of the light-emitting diode and the second conductive pad.

### RELATED APPLICATIONS

The present application is a continuation-in-part application of U.S. application Ser. No. 16/432,918, filed Jun. 5, 2019, which is herein incorporated by reference.

### BACKGROUND

### Field of Invention

The present disclosure relates to an electrical contact structure for a light-emitting diode.

### Description of Related Art

The statements in this section merely provide background information related to the present disclosure and do not necessarily constitute prior art.

Traditional display manufacturing is a standardized process set. In recent years, there are more and more new types of displays such as a micro light-emitting diode display, a mini light-emitting diode display, and a quantum dot light-emitting diode display . . . etc., which are promising to dominate the future display market, and thus new display manufacturing processes are waiting to be set up. There are many steps contained in a manufacturing process set in order to produce one display, and reducing one of the steps thereof can reduce the cost and enhance the efficiency.

### SUMMARY

According to some embodiments of the present disclosure, an electrical contact structure for a light-emitting diode is provided. The electrical contact structure includes a substrate, a first conductive pad, a second conductive pad, the light-emitting diode, a cured positive photoresist layer, and a top electrode. The first conductive pad is on a top surface of the substrate. The second conductive pad is on the top surface of the substrate. The second conductive pad is spaced apart from the first conductive pad. The light-emitting diode is on the first conductive pad. The light-emitting diode includes a bottom electrode, a first type semiconductor layer, an active layer, and a second type semiconductor layer. The bottom electrode is in contact with the first conductive pad. The first type semiconductor layer is on the bottom electrode. The active layer is on the first type semiconductor layer. The second type semiconductor layer is on the active layer, in which a thickness of the second type semiconductor layer is greater than a thickness of the first type semiconductor layer. The cured positive photoresist layer is in contact with the first conductive pad and the light-emitting diode, which exposes a top surface of the second conductive pad through a via hole therein, and exposes a top surface of the light-emitting diode. A height of the top surface of the light-emitting diode relative to the top surface of the substrate is greater than a height of a top surface of the cured positive photoresist layer relative to the top surface of the substrate, and the height of the top surface of the cured positive photoresist layer relative to the top surface of the substrate is greater than a height of the top surface of the second conductive pad relative to the top surface of the substrate. The top electrode covers and is in contact with the top surface of the light-emitting diode, the top surface of the second conductive pad, and the cured positive photoresist layer.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a flow chart of a method of forming a conductive area at a top surface of a light-emitting diode according to some embodiments of the present disclosure;

FIG. 2A is a schematic cross-sectional view of an intermediate stage of a method of forming a conductive area at a top surface of a light-emitting diode according to some embodiments of the present disclosure;

FIG. 2B is a schematic cross-sectional view of an intermediate stage of a method of forming a conductive area at a top surface of a light-emitting diode according to some embodiments of the present disclosure;

FIG. 2C is a schematic cross-sectional view of an intermediate stage of a method of forming a conductive area at a top surface of a light-emitting diode according to some embodiments of the present disclosure;

FIG. 2D is a schematic cross-sectional view of an intermediate stage of a method of forming a conductive area at a top surface of a light-emitting diode according to some embodiments of the present disclosure;

FIG. 2E is a schematic cross-sectional view of an intermediate stage of a method of forming a conductive area at a top surface of a light-emitting diode according to some embodiments of the present disclosure;

FIG. 3A is a schematic cross-sectional view of an electrical contact structure for a light-emitting diode according to some embodiments of the present disclosure;

FIG. 3B is a schematic cross-sectional view of a structure including the light-emitting diode and the second conductive pad of which top surfaces are not exposed;

FIG. 3C is a schematic cross-sectional view of a structure including the light-emitting diode and the second conductive pad of which the top surfaces are exposed; and

FIG. 3D is a schematic cross-sectional view of an electrical contact structure for a light-emitting diode according to some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In various embodiments, the description is made with reference to figures. However, certain embodiments may be practiced without one or more of these specific details, or in combination with other known methods and configurations. In the following description, numerous specific details are set forth, such as specific configurations, dimensions, and processes, etc., in order to provide a thorough understanding of the present disclosure. In other instances, well-known semiconductor processes and manufacturing techniques have not been described in particular detail in order to not unnecessarily obscure the present disclosure. Reference throughout this specification to “one embodiment,” “an embodiment” or the like means that a particular feature, structure, configuration, or characteristic described in connection with the embodiment is included in at least one embodiment of the disclosure. Thus, the appearances of the phrase “in one embodiment,” “in an embodiment” or the like in various places throughout this specification are not necessarily referring to the same embodiment of the disclosure. Furthermore, the particular features, structures, configurations, or characteristics may be combined in any suitable manner in one or more embodiments.

The terms “over,” “to,” “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

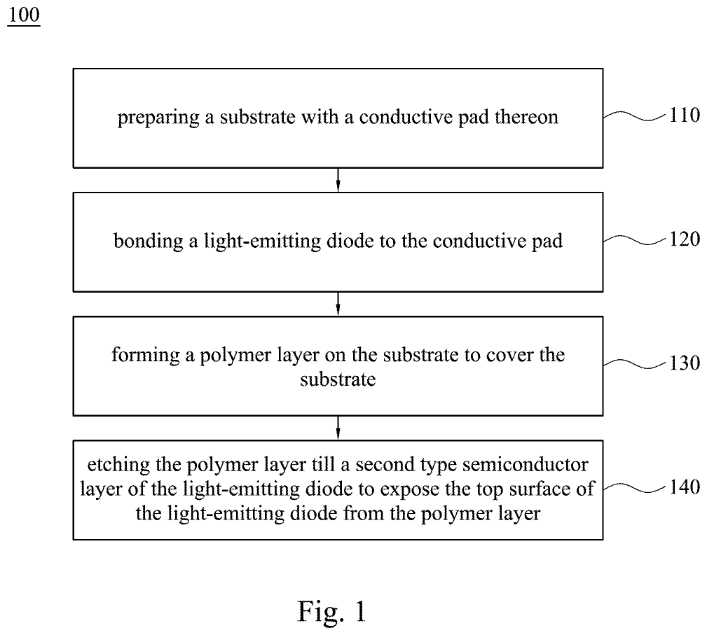

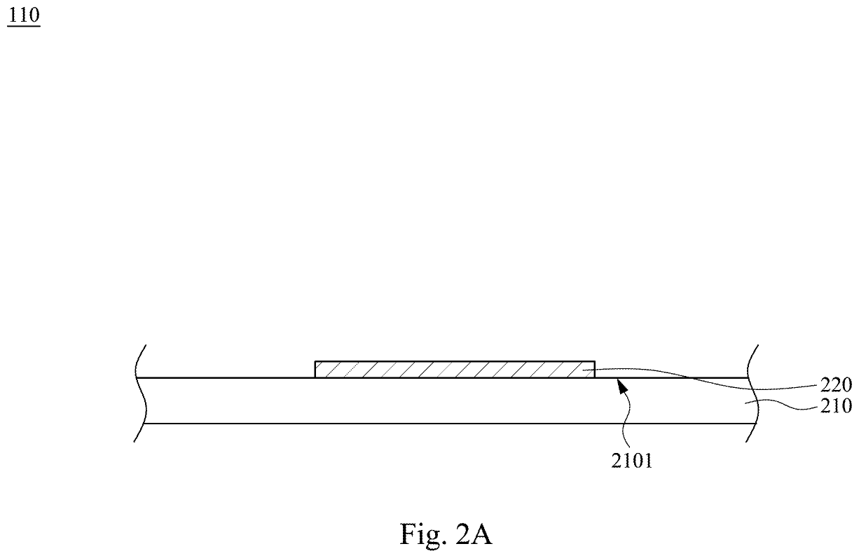

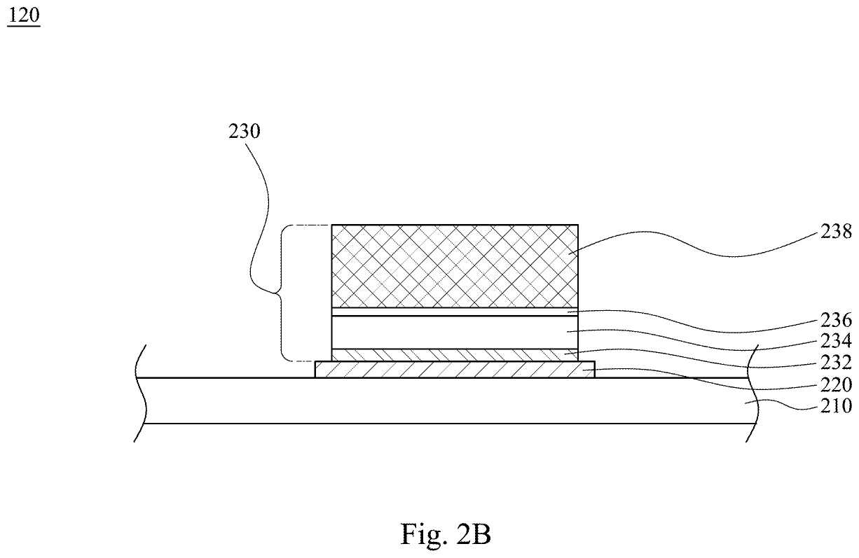

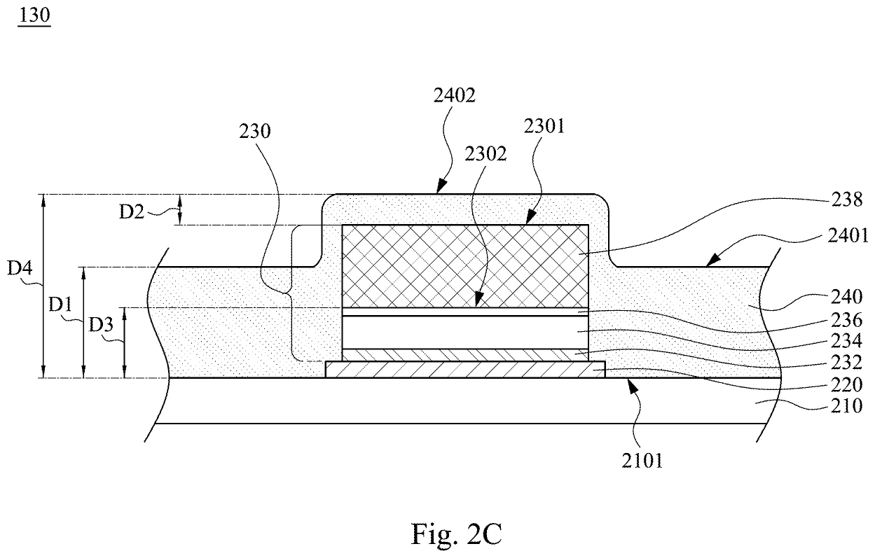

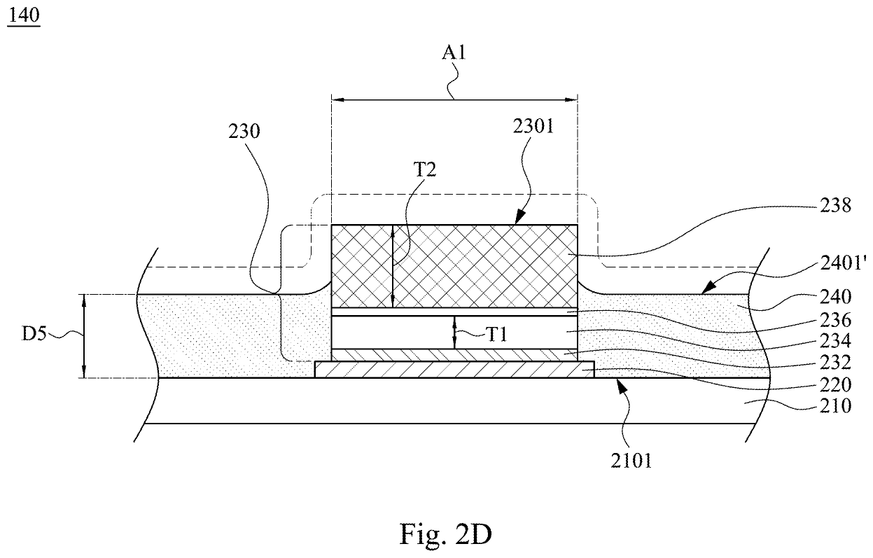

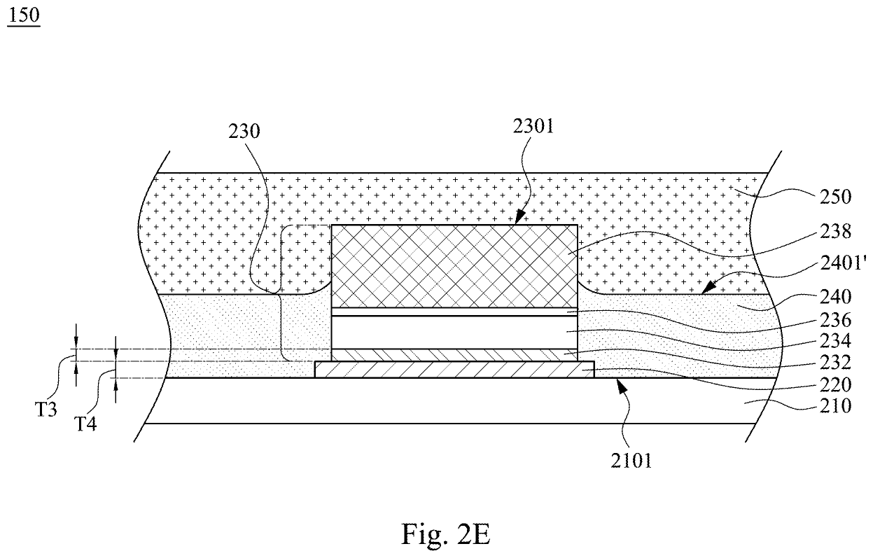

FIG. 1 is a flow chart of a method 100 of forming a conductive area at a top surface of a light-emitting diode according to some embodiments of the present disclosure. FIGS. 2A to 2E are schematic cross-sectional views of intermediate stages of the method 100 of FIG. 1 according to some embodiments of the present disclosure.

Reference is made to FIGS. 1 to 2E. The method 100 of forming a conductive area A1 at a top surface 2301 of a light-emitting diode 230 begins with operation 110 in which a substrate 210 with a conductive pad 220 thereon is prepared (as referred to FIG. 2A). The method continues with operation 120 in which a light-emitting diode 230 is bonded to the conductive pad 220 (as referred to FIG. 2B). The method 100 continues with operation 130 in which a polymer layer 240 is formed on the substrate 210 to cover a top surface 2101 of the substrate 210, the conductive pad 220, and the light-emitting diode 230 (as referred to FIG. 2C). The method 100 continues with operation 140 in which the polymer layer 240 is etched till a second type semiconductor layer 238 of the light-emitting diode 230 to expose the top surface 2301 of the light-emitting diode 230 from the polymer layer 240 (as referred to FIG. 2D).

Although in the previous paragraph only “a” light-emitting diode 230 is mentioned, “multiple” light-emitting diode 230 may be used in practical applications and is still within the scope of the present disclosure, and will not be emphasized in the disclosure. The light-emitting diode 230 demonstrated herein is a vertical type light-emitting diode.

Reference is made to FIG. 2B. The light-emitting diode 230 includes a bottom electrode 232, a first type semiconductor layer 234, an active layer 236, and the second type semiconductor layer 238. In some embodiments, the first type semiconductor layer 234 is on the bottom electrode 232. The active layer 236 is on the first type semiconductor layer 234. The second type semiconductor layer 238 is on the active layer 236. The bottom electrode 232 is in contact with the conductive pad 220 of the substrate 210 when the light-emitting diode 230 is bonded to the conductive pad 220.

Reference is made to FIG. 2C. After the polymer layer 240 is formed on the substrate 210 and the light-emitting diode 230, a difference between a distance D1 from a first surface 2401 of the polymer layer 240 to the top surface 2101 of the substrate 210 and a distance D2 from a second surface 2402 of the polymer layer 240 to a top surface 2301 of the light-emitting diode 230 is greater than a distance D3 from an interface 2302 between the second type semiconductor layer 238 and the active layer 236 to the top surface 2101 of the substrate 210. Briefly speaking, D1−D2>D3. Specifically, a vertical projection of the first surface 2401 projected on the substrate 210 is spaced apart from a vertical projection of the light-emitting diode 230 projected on the substrate 210, and a vertical projection of the second surface 2402 projected on the substrate 210 is overlapped with the vertical projection of the light-emitting diode 230 projected on the substrate 210. In some embodiments, a distance D4 from the second surface 2402 of the polymer layer 240 to the top surface 2101 of the substrate 210 is greater than the distance D1 from the first surface 2401 of the polymer layer 240 to the top surface 2101 of the substrate 210.

Reference is made to FIG. 2D. Due to the above condition: D1−D2>D3, the polymer layer 240 can be etched till the second type semiconductor layer 238 to expose the top surface 2301 of the light-emitting diode 230 from the polymer layer 240 without using any other materials for covering the polymer layer 240 as a mask. Specifically, a step of forming a mask layer to open a window on the polymer layer 240 for etching can be omitted so as to reduce the cost and enhance the manufacturing efficiency. The etching can be performed by ashing, plasma etching (e.g., inductive coupled plasma (ICP) etching or reactive ion etching (RIE)), but should not be limited thereto. Normally, an etching rate on the first surface 2401 of the polymer layer 240 is roughly the same as an etching rate on the second surface 2402 of the polymer layer 240. As a result, after a time period of etching, the first surface 2401 is lowered down to a new first surface 2401′ as shown in FIG. 2D. The second surface 2402 is lowered down until it vanishes to expose the top surface 2301 of the light-emitting diode 230. It is noted that the first type semiconductor layer 234 and the active layer 236 are free from exposing by the polymer layer 240 after the etching. That is, after the etching, the first type semiconductor layer 234 and the active layer 236 are still covered by the polymer layer 240 (at least on side surfaces thereof) to ensure there is an electrical isolation between the second type semiconductor layer 238 and the first type semiconductor layer 234 after a top electrode 250 (see FIG. 2E) is formed on the second type semiconductor layer 238.

In some embodiments when the polymer layer 240 is a positive photoresist layer, the etching can be performed by a partial exposure process followed by a development process. Specifically, the polymer layer 240 is exposed (e.g., by UV light, but should not be limited thereto) under weak exposure dose such that the photo-sensitive materials between the second surface 2402 and the top surface 2301 of the light-emitting diode 230 are all degraded, but the photo-sensitive materials between the first surface 2401 and the top surface 2101 of the substrate 210 are only partially degraded (i.e., only a portion of the photo-sensitive materials close to the first surface 2401 are degraded) due to a thickness difference between the thickness D2 (thinner) and the thickness D1 (thicker). As a result, when the development process is performed to dissolved the exposed photo-sensitive materials, the top surface 2301 of the light-emitting diode 230 is exposed while the top surface 2101 of the substrate 210 is still covered by the photoresist layer.

In some embodiments, a ratio between a thickness T2 of the second type semiconductor layer 238 and a thickness T1 of the first type semiconductor layer 234 is greater than or equal to about 1.5. The thickness relationship between the second type semiconductor layer 238 and the first type semiconductor layer 234 can increase the tolerance of the criterion: D1−D2>D3 as mentioned since a thicker layer (e.g., the second type semiconductor layer 238 in the embodiments herein) faces etching gases in a direction from the light-emitting diode 230 to the second surface 2402 (before etching) of the polymer layer 240. In some embodiments, a thickness D5 of the polymer layer 240 after etching is greater than or equal to about 2 μm, so as to better maintain the electrical isolation between the first type semiconductor layer 234 and the second type semiconductor layer 238 because the largest possible distance D3 is roughly or smaller than about 2 μm. In some embodiments, the first type semiconductor layer 234 is a p-type semiconductor layer, and the second type semiconductor layer 238 is an n-type semiconductor layer. Under this condition, the thicker layer is the n-type semiconductor layer which has lower resistivity compared to the p-type semiconductor layer, which leads to better light-emitting efficiency because the p-type semiconductor layer which has higher resistivity and contact resistance is already fully in contact with the bottom electrode 232 before the light-emitting diode 230 is bonded to the conductive pad 220. In some embodiments, a thickness of the p-type semiconductor layer is about 250 nm and a thickness of the active layer 236 is about 150 nm. In some embodiments, the light-emitting diode 230 further includes an electron blocking layer between the active layer 236 and the p-type semiconductor layer 234 so as to prevent electrons (which flow from the n-type semiconductor layer towards the active layer 236) from flowing out of the active layer 236 (and into the p-type semiconductor layer) and thus the light-emitting efficiency is enhanced.

Reference is made to FIG. 2E. In some embodiments, the method 100 further includes forming the top electrode 250 on the second type semiconductor layer 238 of the light-emitting diode 230 such that the top electrode 250 is in contact with the top surface 2301 of the light-emitting diode 230. Since the polymer layer 240 still covers the active layer 236 and the first type semiconductor layer 234 of the light-emitting diode 230, and the second type semiconductor layer 238 is exposed, the top electrode 250 can be directly formed on the second type semiconductor layer 238 without using any mask layer which is originally used for maintaining the electrical isolation between the second type semiconductor layer 238 and the first type semiconductor layer 234. As a result, the cost is reduced and the manufacturing efficiency is enhanced. Besides, the embodiments of the present disclosure can maintain the electrical isolation between the top electrode 250 and the conductive pad 220 on a site which is absent of light-emitting diode 230 on the conductive pad 220. This kind of unexpected absence sometimes occur due to defects when the light-emitting diodes 230 are massively transferred to the substrate 210. Since the thickness of the polymer layer 240 above the conductive pad 220 becomes thicker (e.g., having the thickness D1) when there is no light-emitting diode 230 thereon, the polymer layer 240 prevents the conductive pad 220 from being exposed during the etching and thus maintaining the electrical isolation as mentioned.

In some embodiments, the top electrode 250 is transparent so that light emitted from the light-emitting diode 230 can transmit through the top electrode 250 to enhance a light extraction efficiency. The polymer layer 240 can be poly(methyl methacrylate) (PMMA), epoxy, polycarbonate (PC), polyethylene terephthalate (PET), polydimethylsiloxane (PDMS), polystyrene (PS), phenol-formaldehyde resin (phenolic resin), or polyimide (PI), but should not be limited thereto. In some embodiments, the polymer layer 240 is formed by spin coating or slit coating so as to form the thickness relationship as shown above in one coating step. In some embodiments, the polymer layer 240 includes titanium oxide (TiO₂) nanoparticles to increase a refractive index of the polymer layer 240 to further enhance the light extraction efficiency.

In some embodiments, the light-emitting diode 230 is a micro light-emitting diode having a lateral length less than or equal to about 100 μm. It is further noted that a preferable condition for a sum of a thickness T3 of the bottom electrode 232 and a thickness T4 of the conductive pad 220 is smaller than or equal to about 2 μm. The 2 μm is a balance of size (i.e., the lateral length about 100 μm) of the micro light-emitting diode and a capability to have an interstitial diffusion between the bottom electrode 232 and the conductive pad 220 when the micro light-emitting diode is bonded to the conductive pad 220. As a result, no melting process is performed during the bonding, and the micro light-emitting diode is better protected from damaging during bonding and a position of the micro light-emitting diode 230 relative to the conductive pad 220 can be better controlled.

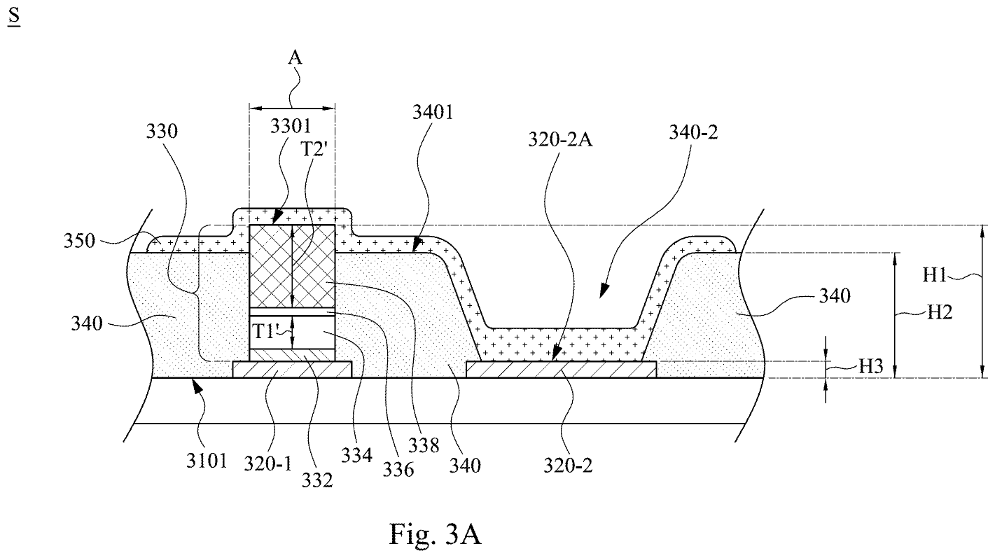

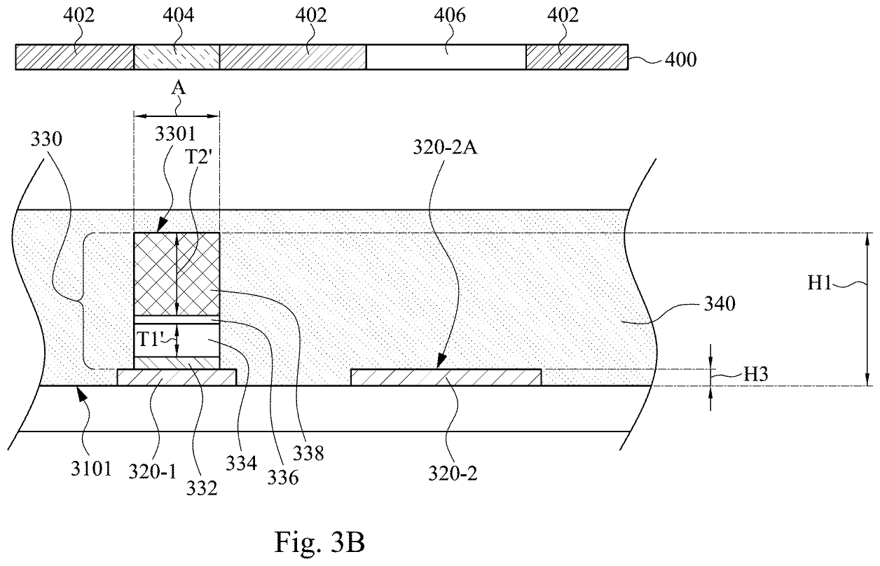

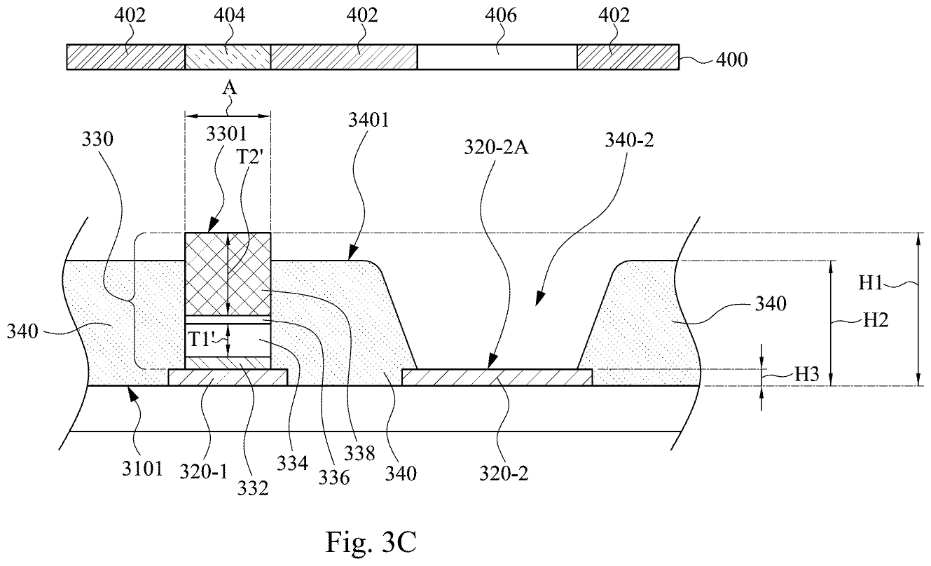

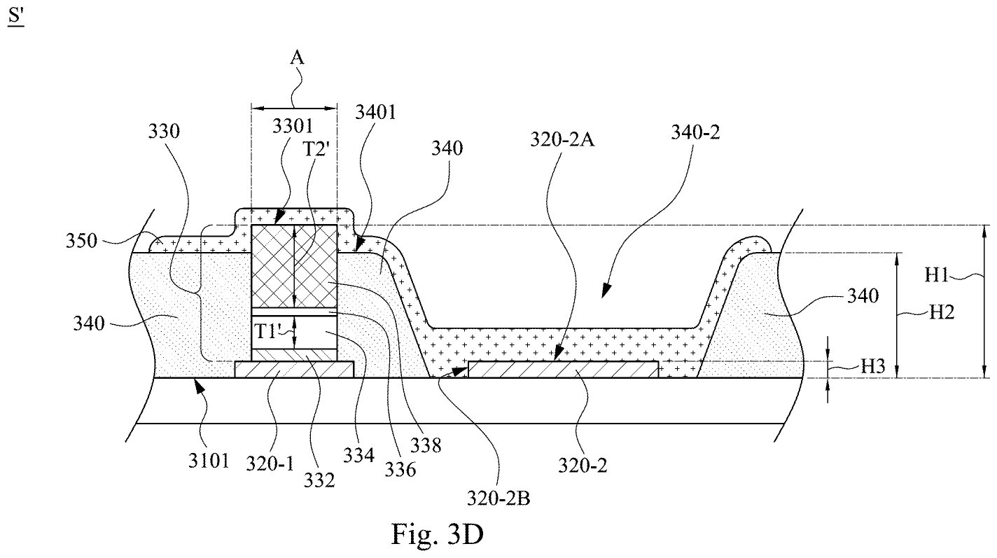

Reference is made to FIG. 3A. FIG. 3A is a schematic cross-sectional view of an electrical contact structure S for a light-emitting diode 330 according to some embodiments of the present disclosure. In some embodiments, the electrical contact structure S includes a substrate 310, a first conductive pad 320-1, a second conductive pad 320-2, the light-emitting diode 330, a cured positive photoresist layer 340, and a top electrode 350. The first conductive pad 320-1 is on a top surface 3101 of the substrate 310. The second conductive pad 320-2 is on the top surface 3101 of the substrate. The second conductive pad 320-2 is spaced apart from the first conductive pad 320-1. The light-emitting diode 330 is on the first conductive pad 320-1. The light-emitting diode 330 includes a bottom electrode 332, a first type semiconductor layer 334, an active layer 336, and a second type semiconductor layer 338. The bottom electrode 332 is in contact with the first conductive pad 320-1. The first type semiconductor layer 334 is on the bottom electrode 332. The active layer 336 is on the first type semiconductor layer 334. The second type semiconductor layer 338 is on the active layer 336. In some embodiments, a thickness T2′ of the second type semiconductor layer 338 is greater than a thickness T1′ of the first type semiconductor layer 334.

The cured positive photoresist layer 340 is in contact with the first conductive pad 320-1 and the light-emitting diode 330, in which a top surface 320-2A of the second conductive pad 320-2 is exposed through a via hole 340-2 therein and a top surface 3301 of the light-emitting diode 330 is exposed. The cured positive photoresist layer 340 is “cured” to be solid enough to act as a dielectric layer in the electrical contact structure S. In some embodiments, the cured positive photoresist layer 340 is an UV cured photoresist layer, a thermal cured photoresist layer, or a mixture thereof. A height H1 of the top surface 3301 of the light-emitting diode 330 relative to the top surface 3101 of the substrate 310 is greater than a height H2 of a top surface 3401 of the cured positive photoresist layer 340 relative to the top surface 3101 of the substrate 310, and the height H2 is greater than a height H3 of the top surface 320-2A of the second conductive pad 320-2 relative to the top surface 3101 of the substrate 310. The top electrode 350 covers and is in contact with the top surface 3301 of the light-emitting diode 330, the top surface 320-2A of the second conductive pad 320-2, and the cured positive photoresist layer 340.

In some embodiments, the cured positive photoresist layer 340 is transparent, in which a transmittance of the cured positive photoresist layer 340 is greater than 80%, so that more percentage of light emitted from the light-emitting diode 330 can be transmitted out of the electrical contact structure S to enhance the light extraction efficiency. In some embodiments, the cured positive photoresist layer 340 is formed by spin coating or slit coating. In some embodiments, the cured positive photoresist layer 340 is in contact with the bottom electrode 332, the first type semiconductor layer 324, the active layer 326, and the second type semiconductor layer 328. In some embodiments, an area A of the top surface 3301 of the light-emitting diode 330 exposed from the cured positive photoresist layer 340 is smaller than or equal to about 50×50 μm². The limitation of the area A indicates that the electrical contact structure S may be better performed in a range when the light-emitting diode 330 is a micro light-emitting diode. In some embodiments, a ratio between the thickness T2′ of the second type semiconductor layer 338 and the thickness T1′ of the first type semiconductor layer 334 is greater than or equal to about 1.5. A benefit of the restriction on the thickness relation is also a process tolerance issue, which is similar to the benefit of the thickness relation between the thickness T2 of the second type semiconductor layer 238 and a thickness T1 of the first type semiconductor layer 234 as mentioned in paragraphs illustrating FIG. 2C, which will be omitted herein. In some embodiments, the first type semiconductor layer 334 is a p-type semiconductor layer, and the second type semiconductor layer 338 is an n-type semiconductor layer. The benefit of the chosen types of semiconductor layer has been mentioned above, and will be omitted herein.

The role of the cured positive photoresist layer 340 in the present embodiments is similar to that of the polymer layer 240 in the previous embodiments as illustrated by FIGS. 2A to 2. However, the electrical contact structure S can be specifically fabricated by a method similar to a photolithography using the cured positive photoresist layer 340, but should not be limited thereto. Reference is made to FIGS. 3B and 3C. FIG. 3B is a schematic cross-sectional view of a structure including the light-emitting diode 330 and the second conductive pad 320-2 of which top surfaces 3301, 320-2A are not exposed. FIG. 3C is a schematic cross-sectional view of a structure including the light-emitting diode 330 and the second conductive pad 320-2 of which the top surfaces 3301, 320-2A are exposed. In some embodiments, a photo mask 400 having a first portion 402, a second portion 404, and a third portion 406 is provided for the fabrication. A relation on the transparency of light (e.g., UV light, but should not be limited thereto) is: first portion 402<second portion 404<third portion 406. In some embodiments, the first portion 402 is opaque, the second portion 404 is semi-transparent, and the third portion 406 is transparent. In this configuration, a grey tone exposure can be performed and different exposure dose can be equivalently performed in one exposure stage and to form the exposed top surface 3301 of the light-emitting diode 330 and the exposed top surface 320-2A of the second conductive pad 320-2. Specifically, the second portion 404 corresponds to a region with the top surface 3301 therein, and the third portion 406 corresponds to a region with the top surface 320-2A therein. The criterion for the correspondence is a thickness of the cured positive photoresist layer 340 intended to be removed during a development stage after the exposure stage.

Reference is made to FIG. 3D. FIG. 3D is a schematic cross-sectional view of an electrical contact structure S′ for the light-emitting diode 330 according to some embodiments of the present disclosure. A difference between the embodiments as illustrated by FIG. 3D and the embodiments as illustrated by FIG. 3A is that not only the top surface 320-2A but also a side surface 320-2B of the second conductive pad 320-2 is exposed from the cured positive photoresist layer 340.

In summary, a method of forming a conductive area at a top surface of a light-emitting diode and an electrical contact structure for a light-emitting diode are provided which is able to decrease number of stages of manufacturing or making processes easier to be conducted. As such, the cost is reduced and the manufacturing efficiency is increased.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the method and the structure of the present disclosure without departing from the scope or spirit of the disclosure. In view of the foregoing, it is intended that the present disclosure cover modifications and variations of this disclosure provided they fall within the scope of the following claims.

What is claimed is:

1. An electrical contact structure for a light-emitting diode, comprising:
a substrate;
a first conductive pad on a top surface of the substrate;
a second conductive pad on the top surface of the substrate, wherein the second conductive pad is spaced apart from the first conductive pad;
the light-emitting diode on the first conductive pad, comprising:
a bottom electrode in contact with the first conductive pad;
a first type semiconductor layer on the bottom electrode;
an active layer on the first type semiconductor layer; and
a second type semiconductor layer on the active layer, wherein a thickness of the second type semiconductor layer is greater than a thickness of the first type semiconductor layer;
a cured positive photoresist layer in contact with the first conductive pad and the light-emitting diode, exposing a top surface of the second conductive pad through a via hole therein, and exposing a top surface of the light-emitting diode, wherein a height of the top surface of the light-emitting diode relative to the top surface of the substrate is greater than a height of a top surface of the cured positive photoresist layer relative to the top surface of the substrate, and the height of the top surface of the cured positive photoresist layer relative to the top surface of the substrate is greater than a height of the top surface of the second conductive pad relative to the top surface of the substrate; and
a top electrode covering and in contact with the top surface of the light-emitting diode, the top surface of the second conductive pad, and the cured positive photoresist layer.

2. The electrical contact structure of claim 1, wherein the cured positive photoresist layer is in contact with the bottom electrode, the first type semiconductor layer, the active layer, and the second type semiconductor layer.

3. The electrical contact structure of claim 1, wherein a transmittance of the cured positive photoresist layer is greater than 80%.

4. The electrical contact structure of claim 1, wherein a ratio between a thickness of the second type semiconductor layer and a thickness of the first type semiconductor layer is greater than or equal to about 1.5.

5. The electrical contact structure of claim 1, wherein the first type semiconductor layer is a p-type semiconductor layer, and the second type semiconductor layer is an n-type semiconductor layer.

6. The electrical contact structure of claim 1, wherein the cured positive photoresist layer is formed by spin coating or slit coating.

7. The electrical contact structure of claim 1, wherein the first type semiconductor layer and the active layer are free from exposing by the cured positive photoresist layer.

8. The electrical contact structure of claim 1, wherein the cured positive photoresist layer is a UV cured photoresist layer, a thermal cured photoresist layer, or a mixture thereof.
